(19) United States
(12) Patent Application Publication
(10) Pub. No.: US 2022/0392900 A1
(43) Pub. Date: Dec. 8, 2022

(54) MEMORY DEVICE USING SEMICONDUCTOR ELEMENT AND METHOD FOR MANUFACTURING THE SAME

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 17/884,820

(22) Filed: Aug. 10, 2022

Related U.S. Application Data
(63) Continuation-in-part of application No. 17/706,071, filed on Mar. 28, 2022.
Application No. 17/706,071 is a continuation of application No. PCT/JP2021/013220, filed on Mar. 29, 2021.

(51) Int. Cl. H01L 27/108; G11C 11/404; G11C 11/4096

(52) U.S. Cl. CPC H01L 27/10802; G11C 11/404; G11C 11/4096

(57) ABSTRACT

There are an N⁺ layer connected to a source line SL and an N⁺ layer connected to a bit line BL at both ends of a Si pillar standing on a substrate in a perpendicular direction, a P⁺ layer connected to the N⁺ layer, a first gate insulating layer surrounding the Si pillar, a first gate conductor layer surrounding the first gate insulating layer and connected to a plate line PL, and a second gate conductor layer surrounding a gate HfO₂ layer surrounding the Si pillar and connected to a word line WL. The voltages applied to the source line SL, the plate line PL, the word line WL, and the bit line BL are controlled to perform a data hold operation of holding a group of holes generated by an impact ionization phenomenon or a gate-induced drain leakage current inside a channel region of the Si pillar and a data erase operation of removing the group of holes from the channel region.

### RELATED APPLICATIONS

The present application is a continuation-in-part application of Ser. No. 17/706,071, filed Mar. 28, 2022, which claims priority under 35 U.S.C. § 119 to PCT/JP2021/013220, filed on Mar. 29, 2021, the entire contents of which are incorporated herein by reference.

### BACKGROUND OF THE INVENTION

### 1. Field of the Invention

The present invention relates to memory devices using semiconductor elements and methods for manufacturing the memory devices.

### 2. Description of the Related Art

Recently, there has been a need for higher degrees of integration and higher performance of memory elements in the development of large-scale integration (LSI) technology.

A typical planar MOS transistor has a channel extending in a direction parallel to the upper surface of a semiconductor substrate. In contrast, an SGT has a channel extending in a direction perpendicular to the upper surface of a semiconductor substrate (see, for example, PTL 1 and NPL 1). Thus, SGTs can be formed in semiconductor devices at a higher density than planar MOS transistors. The use of SGTs as select transistors allows devices, such as dynamic random-access memory (DRAM; see, for example, NPL 2), which has capacitors connected thereto, phase-change memory (PCM; see, for example, NPL 3) and resistive random-access memory (RRAM; see, for example, NPL 4), which have variable-resistance elements connected thereto, and magneto-resistive random-access memory (MRAM; see, for example, NPL 5), in which the resistance changes as the magnetic spin orientation changes with current, to have a higher degree of integration. There are also, for example, DRAM memory cells composed of a single MOS transistor without having a capacitor (see NPL 7). The present application relates to a dynamic flash memory that can be composed only of MOS transistors without having variable-resistance elements or capacitors.

FIGS. 8A-8D illustrate the write operation of a DRAM memory cell composed of a single MOS transistor without having a capacitor, as mentioned above, FIGS. 9A-9B illustrate a problem with its operation, and FIGS. 10A-10C illustrate the read operation (see NPLs 7 to 10).

FIGS. 8A-8D illustrate the write operation of the DRAM memory cell. FIG. 8A illustrates a “1” written state. Here, the memory cell is formed on an SOI substrate 100. A source N⁺ layer 103 (a semiconductor region containing a high concentration of a donor impurity is hereinafter referred to as “N⁺ layer”) having a source line SL connected thereto, a drain N⁺ layer 104 having a bit line BL connected thereto, and a gate conductive layer 105 having a word line WL connected thereto are formed by a floating body 102 of a MOS transistor 110a. The DRAM memory cell is composed of the single MOS transistor 110a without having a capacitor. A SiO₂ layer 101 of the SOI substrate is disposed directly under and in contact with the floating body 102. When “1” is written in the memory cell composed of the single MOS transistor 110a, the MOS transistor 110a is operated in the saturation region. Specifically, an electron channel 107 extending from the source N⁺ layer 103 has a pinch-off point 108 and does not reach the drain N⁺ layer 104 having the bit line connected thereto. When the bit line BL connected to the drain N⁺ layer 104 and the word line WL connected to the gate conductive layer 105 in this way are both set to a high voltage to operate the MOS transistor 110a such that the gate voltage is about half the drain voltage, the electric field intensity is maximized at the pinch-off point 108 near the drain N⁺ layer 104. As a result, accelerated electrons flowing from the source N⁺ layer 103 toward the drain N⁺ layer 104 collide with the Si lattice, and the kinetic energy lost in the collision generates electron-hole pairs. Most of the generated electrons (not illustrated) reach the drain N⁺ layer 104. In addition, an extremely small proportion of very hot electrons traverse the gate oxide film 109 to reach the gate conductive layer 105. Holes 106 generated at the same time charge the floating body 102. In this case, the generated holes contribute to an increase in majority carriers since the floating body 102 is P-type Si. When the floating body 102 is filled with the generated holes 106, and the voltage of the floating body 102 is higher than that of the source N⁺ layer 103 by Vb or more, additional generated holes are discharged to the source N⁺ layer 103. Here, Vb is the built-in voltage of the PN junction between the source N⁺ layer 103 and the P layer, namely, the floating body 102, and is about 0.7 V. FIG. 8B illustrates a situation in which the floating body 102 is charged to saturation with the generated holes 106.

Next, the “0” write operation of the memory cell 110 will be described using FIG. 8C. A memory cell 110a having “1” written therein and a memory cell 110b having “0” written therein are randomly present for the common select word line WL. FIG. 8C illustrates a situation in which a “1” written state is rewritten to a “0” written state. During “0” writing, the voltage of the bit line BL is negatively biased, and the PN junction between the drain N⁺ layer 104 and the P layer, namely, the floating body 102, is forward-biased. As a result, the holes 106 generated in the floating body 102 in advance in the previous cycle flows into the drain N⁺ layer 104 connected to the bit line BL. Upon completion of the write operation, two memory cell states, i.e., a memory cell 110a (FIG. 8B) filled with the generated holes 106 and a memory cell 110b (FIG. 8C) from which the generated holes have been ejected, are obtained. The potential of the floating body 102 of the memory cell 110a filled with the holes 106 is higher than that of the floating body 102 having no generated holes therein. Thus, the threshold voltage of the memory cell 110a is lower than the threshold voltage of the memory cell 110b. This situation is illustrated in FIG. 8D.

Next, a problem with the operation of the memory cell composed of a single MOS transistor will be described using FIGS. 9A-9B. As illustrated in FIG. 9A, the capacitance C_{FB} of the floating body 102 is the sum of the capacitance C_{WL} between the gate having the word line connected thereto and the floating body 102, the junction capacitance C_{SL} of the PN junction between the source N⁺ layer 103 having the source line connected thereto and the floating body 102, and the junction capacitance C_{BL} of the PN junction between the drain N⁺ layer 103 having the bit line connected thereto and the floating body 102, as expressed by:

C_{FB}=C_{WL}+C_{BL}+C_{SL} (1)

Hence, when the word line voltage V_{WL} oscillates during writing, it affects the voltage of the floating body 102, which serves as the storage node (contact) of the memory cell. This situation is illustrated in FIG. 9B. As the word line voltage V_{WL} increases from 0 V to V_{ProgWL} during writing, the voltage V_{FB} of the floating body 102 increases from a voltage V_{FB1} in the initial state before the change in word line voltage to V_{FB2} due to capacitive coupling with the word line. The change in voltage ΔV_{FB} is expressed by:

$$\begin{matrix}\begin{matrix}\begin{matrix}{ΔV}_{FB} = {V}_{FB 2} - {V}_{FB 1} \\ = {C}_{WL} / ( {C}_{WL} + {C}_{BL} + {C}_{SL} ) \times {V}_{ProgWL}\end{matrix} & ( 2 )\end{matrix} \\ Here , \\ \begin{matrix}β = {C}_{WL} / ( {C}_{WL} + {C}_{BL} + {C}_{SL} ) & ( 3 )\end{matrix}\end{matrix}$$

where β is referred to as coupling rate. In this memory cell, C_{WL} has a considerable contribution ratio, for example, C_{WL}:C_{BL}:C_{SL}=8:1:1. In this case, β=0.8. For example, when the word line transitions from 5 V during writing to 0 V upon completion of writing, the floating body 102 is subjected to oscillation noise, i.e., 5 V×β=4 V, due to capacitive coupling between the word line and the floating body 102. This causes a problem in that it is impossible to ensure sufficient margin of potential difference between the “1” potential and “0” potential of the floating body during writing.

FIGS. 10A 10C illustrate the read operation. FIG. 10A illustrates a “1” written state, and FIG. 10B illustrates a “0” written state. In practice, however, even if Vb has been written in the floating body 102 by “1” writing, the floating body 102 is lowered to a negative bias when the word line returns to 0 V upon completion of writing. When “0” is written, the floating body 102 is more negatively biased, which makes it impossible to ensure sufficient margin of potential difference between “1” and “0” during writing. This limited margin of operation is a considerable problem with this DRAM memory cell. In addition, a challenge exists in achieving higher density of DRAM memory cells.

In addition, there are twin-transistor memory elements in which one memory cell is formed using two MOS transistors on a silicon-on-insulator (SOI) layer (see, for example, PTLs 4 and 5). In these elements, an N⁺ layer serving as a source or drain and separating the floating body channels of the two MOS transistors is formed in contact with an insulating layer. Because this N⁺ layer is in contact with the insulating layer, the floating body channels of the two MOS transistors are electrically isolated. A group of holes serving as signal charges are accumulated in the floating body channel of one transistor. As described above, the voltage of the floating body channel having the holes accumulated therein changes considerably as a pulse voltage is applied to the gate electrode of the adjacent MOS transistor, as shown in equation (2). Thus, as described using FIGS. 8A-8D to 10A-10C, it is impossible to ensure a sufficiently large margin of operation between “1” and “0” during writing (see, for example, NPL 15, FIGS. 8A-8D).

### CITATION LIST

### Patent Literature

[PTL 1] Japanese Unexamined Patent Application Publication No. 2-188966

[PTL 2] Japanese Unexamined Patent Application Publication No. 3-171768

[PTL 3] Japanese Patent No. 3957774

[PTL 4] US2008/0137394 A1

[PTL 5] US2003/0111681 A1

### Non Patent Literature

[NPL 1] Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)

[NPL 2] H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference (2011)

[NPL 3] H. S. Philip Wong, S. Raoux, S. Kim, Jiale Liang, J. R. Reifenberg, B. Rajendran, M. Asheghi, and K. E. Goodson: “Phase Change Memory,” Proceeding of IEEE, Vol. 98, No. 12, December, pp. 2201-2227 (2010)

[NPL 4] T. Tsunoda, K .Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3 V,” IEDM (2007)

[NPL 5] W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)

[NPL 6] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)

[NPL 7] J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)

[NPL 8] T. Ohsawa, K. Fujita, T. Higashi, Y. Iwata, T. Kajiyama, Y. Asao, and K. Sunouchi: “Memory design using a one-transistor gain cell on SOT,” IEEE JSSC, Vol. 37, No. 11, pp 1510-1522 (2002).

[NPL 9] T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, and A. Nitayama: “Floating Body RAM Technology and its Scalability to 32 nm Node and Beyond,” IEEE IEDM (2006).

[NPL 10] E. Yoshida: “A Capacitorless 1T-DRAM Technology Using Gate-Induced Drain-Leakage (GIDL) Current for Low-Power and High-Speed Embedded Memory,” IEEE IEDM (2006).

[NPL 11] J. Y. Song, W. Y. Choi, J. H. Park, J. D. Lee, and B-G. Park: “Design Optimization of Gate-All-Around (GAA) MOSFETs,” IEEE Trans. Electron Devices, Vol. 5, No. 3, pp. 186-191, May 2006.

[NPL 12] N. Loubet, et al.: “Stacked Nanosheet Gate-All-Around Transistor to Enable Scaling Beyond FinFET,” 2017 IEEE Symposium on VLSI Technology Digest of Technical Papers, T17-5, T230-T231, June 2017.

[NPL 13] H. Jiang, N. Xu, B. Chen, L. Zengl, Y. He, G. Du, X. Liu, and X. Zhang: “Experimental investigation of self heating effect (SHE) in multiple-fin SOI FinFETs,” Semicond. Sci. Technol. 29 (2014) 115021 (7 pp).

[NPL 14] E. Yoshida and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006.

[NPL 15] F. Morishita, H. Noda, I. Hayashi, T. Gyohten, M. Okamoto, T. Ipposhi, S. Maegawa, K. Dosaka, and K. Arimoto: “Capacitorless Twin-Transistor Random Access Memory (TTRAM) on SOI,” IEICE Trans. Electron., Vol. E90-c., No. 4, pp. 765-771 (2007)

### SUMMARY OF THE INVENTION

### Technical Problem

Capacitorless one-transistor DRAM (gain cell) configured as a memory device using an SGT has a problem in that, when the word line potential oscillates during data reading or writing, it is directly transmitted as noise to the SGT body in the floating state because of the large capacitive coupling between the word line and the SGT body. This causes the problem of erroneous reading and erroneous rewriting of stored data and thus makes it difficult to put capacitorless one-transistor DRAM (gain cell) into practical use. In addition to solving the above problem, there is a need for higher density of DRAM memory cells.

### Solution to Problem

To solve the above problems, a memory device using a semiconductor element of the present invention includes: a semiconductor base standing on a substrate in a direction perpendicular to the substrate or extending on the substrate in a direction parallel to the substrate; a first impurity layer and a second impurity layer at both ends of the semiconductor base; a third impurity layer formed in the semiconductor base at one or both of a position adjoining the first impurity layer and a position adjoining the second impurity layer, the third impurity layer having an opposite conductivity to the first impurity layer and the second impurity layer; a first gate insulating layer surrounding a portion or entirety of a side surface of the semiconductor base between the first impurity layer and the second impurity layer, the first gate insulating layer being in contact with or in proximity to the first impurity layer; a second gate insulating layer surrounding a portion or entirety of the side surface of the semiconductor base, the second gate insulating layer being connected to the first gate insulating layer and being in contact with or in proximity to the second impurity layer; a first gate conductor layer covering the first gate insulating layer; a second gate conductor layer covering the second gate insulating layer; a first insulating layer between the first gate conductor layer and the second gate conductor layer; a first wiring conductor layer connected to the first impurity layer; a second wiring conductor layer connected to the second impurity layer; a third wiring conductor layer connected to the first gate conductor layer; a fourth wiring conductor layer connected to the second gate conductor layer; and a channel semiconductor layer comprising a first channel semiconductor layer of the semiconductor base that is covered by the first gate insulating layer and a second channel semiconductor layer of the semiconductor base that is covered by the second gate insulating layer, wherein a memory write operation is performed by controlling voltages applied to the first wiring conductor layer, the second wiring conductor layer, the third wiring conductor layer, and the fourth wiring conductor layer to perform an operation of causing an impact ionization phenomenon or a gate-induced drain leakage current with a current flowing between the first impurity layer and the second impurity layer in a first boundary region between the first channel semiconductor layer and the second channel semiconductor layer, a second boundary region between the first impurity layer and the first channel semiconductor layer, or a third boundary region between the second impurity layer and the second channel semiconductor layer, an operation of removing, of a group of generated electrons and a group of generated holes, the group of electrons from the first impurity layer or the second impurity layer, and an operation of allowing some or all of the group of holes to remain in one or both of the first channel semiconductor layer and the second channel semiconductor layer, and a memory erase operation is performed by controlling the voltages applied to the first wiring conductor layer, the second wiring conductor layer, the third wiring conductor layer, and the fourth wiring conductor layer to extract a remainder of the group of holes from one or both of the first impurity layer and the second impurity layer (first invention).

In the above first invention, a wiring line connected to the first impurity layer is a source line, a wiring line connected to the second impurity layer is a bit line, a wiring line connected to the first gate conductor layer is a first drive control line, a wiring line connected to the second gate conductor layer is a word line, and the memory erase operation and the memory write operation are performed using voltages applied to the source line, the bit line, the first drive control line, and the word line (second invention).

In the above second invention, the third impurity layer is formed at a position adjoining the second impurity layer connected to the bit line, and the third impurity layer is not formed at a position adjoining the first impurity layer connected to the source line (third invention).

In the above second invention, the third impurity layer is formed at a position adjoining the first impurity layer connected to the source line, and the third impurity layer is not formed at a position adjoining the second impurity layer connected to the bit line (fourth invention).

In the above first invention, the first gate capacitance between the first gate conductor layer and the first channel semiconductor layer is greater than the second gate capacitance between the second gate conductor layer and the second channel semiconductor layer (fifth invention).

In the above first invention, the semiconductor base is formed perpendicular to the substrate, and the memory device includes: the first impurity layer formed in the semiconductor base near the substrate; the first channel semiconductor layer formed above the first impurity layer in the semiconductor base; the second channel semiconductor layer formed above the first channel semiconductor layer in the semiconductor base; the second impurity layer formed above the second channel semiconductor layer in the semiconductor base; the first gate insulating layer surrounding the first channel semiconductor layer; the second gate insulating layer surrounding the second channel semiconductor layer; the first gate conductor layer surrounding the first gate insulating layer; the second gate conductor layer surrounding the second gate insulating layer; the first insulating layer between the first gate conductor layer and the second gate conductor layer; and the third impurity layer formed in the semiconductor base at one or both of a position adjoining the first impurity layer and a position adjoining the second impurity layer, the third impurity layer having an opposite conductivity to the first impurity layer and the second impurity layer (sixth invention).

### BRIEF DESCRIPTION OF THE DRAWINGS

FIG. 1 is an illustration of the structure of a memory device including an SGT according to a first embodiment.

FIGS. 2A, 2B and 2C include illustrations for describing the erase operation mechanism of the memory device including an SGT according to the first embodiment.

FIGS. 3A, 3B and 3C include illustrations for describing the write operation mechanism of the memory device including an SGT according to the first embodiment.

FIG. 4AA, 4AB and 4AC include illustrations for describing the read operation mechanism of the memory device including an SGT according to the first embodiment.

FIGS. 4BA, 4BB, 4BC and 4BD include illustrations for describing the read operation mechanism of the memory device including an SGT according to the first embodiment.

FIGS. 5AA, 5AB and 5AC include illustrations for describing a method for manufacturing the memory device including an SGT according to the first embodiment.

FIGS. 5BA, 5BB and 5BC include illustrations for describing the method for manufacturing the memory device including an SGT according to the first embodiment.

FIGS. 5CA, 5CB and 5CC include illustrations for describing the method for manufacturing the memory device including an SGT according to the first embodiment.

FIGS. 5DA, 5DB and 5DC include illustrations for describing the method for manufacturing the memory device including an SGT according to the first embodiment.

FIGS. 5EA, 5EB and 5EC include illustrations for describing the method for manufacturing the memory device including an SGT according to the first embodiment.

FIGS. 5FA, 5FB, 5FC and 5FD include illustrations for describing the method for manufacturing the memory device including an SGT according to the first embodiment.

FIGS. 5GA, 5GB, 5GC and 5GD include illustrations for describing the method for manufacturing the memory device including an SGT according to the first embodiment.

FIGS. 5HA, 5HB and 5HC include illustrations for describing the method for manufacturing the memory device including an SGT according to the first embodiment.

FIG. 5I is an illustration for describing the method for manufacturing the memory device including an SGT according to the first embodiment.

FIG. 6 is an illustration for describing a method for manufacturing a memory device including an SGT according to a second embodiment.

FIG. 7 is an illustration for describing a method for manufacturing a memory device including an SGT according to a third embodiment.

FIGS. 8A, 8B, 8C and 8D include illustrations for describing the problem with the operation of the example conventional capacitorless DRAM memory cell.

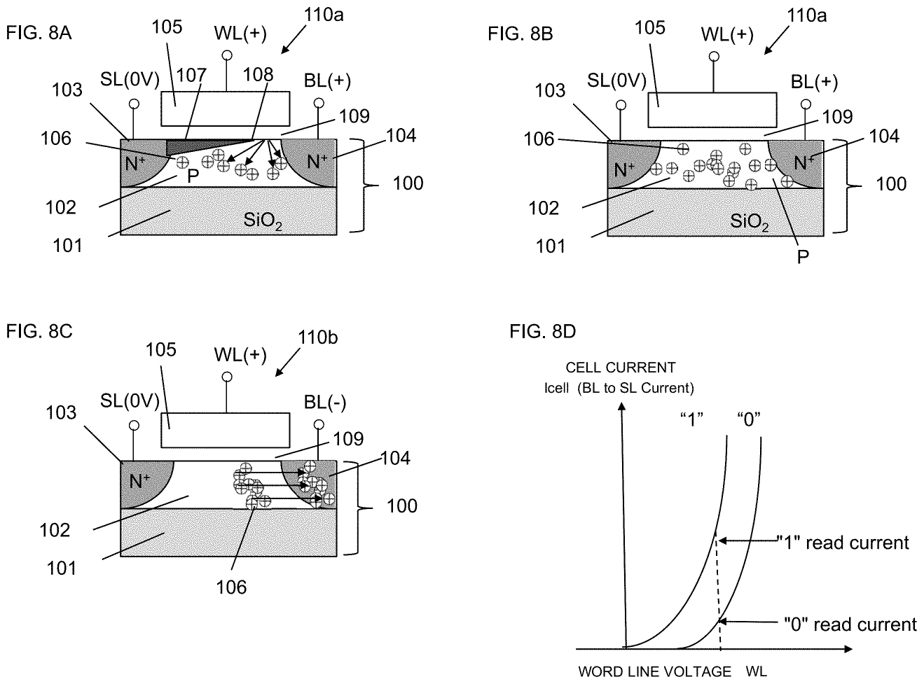

FIGS. 9A and 9B includes illustrations for describing the problem with the operation of the example conventional capacitorless DRAM memory cell.

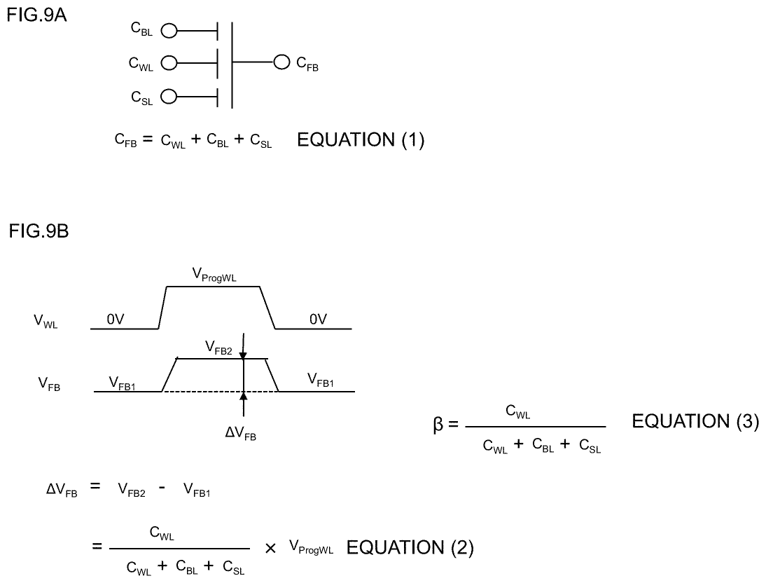

FIGS. 10A, 10B and 10C include illustrations showing the read operation of the example conventional capacitorless DRAM memory cell.

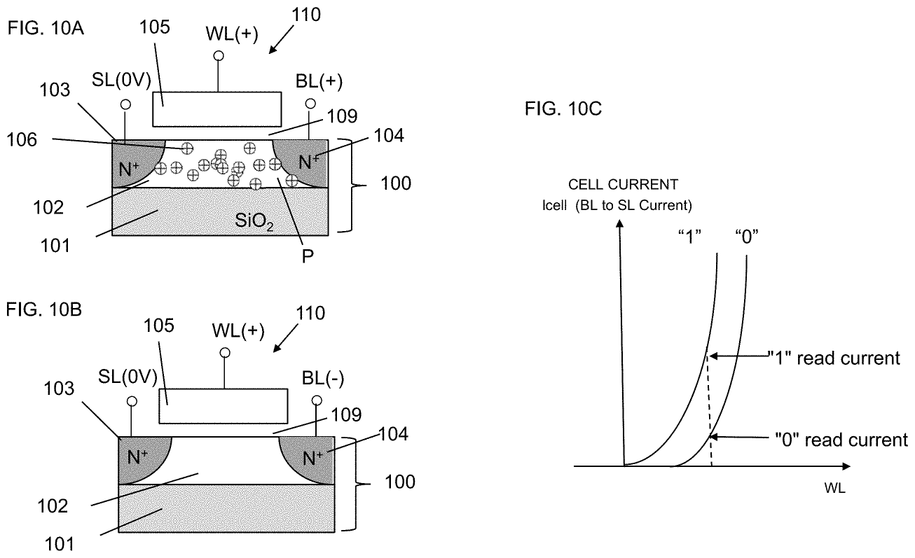

### DETAILED DESCRIPTION OF THE PREFERRED EMBODIMENTS

A method for manufacturing a memory device using a semiconductor element (hereinafter referred to as dynamic flash memory) according to the present invention will be described below with reference to the drawings.

### First Embodiment

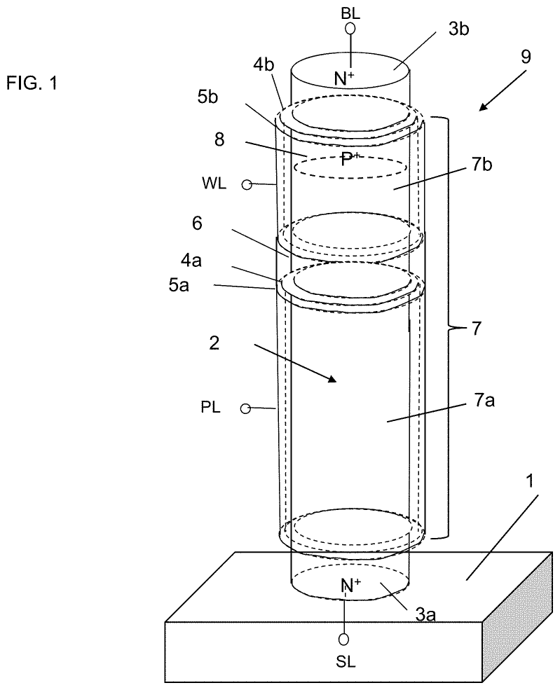

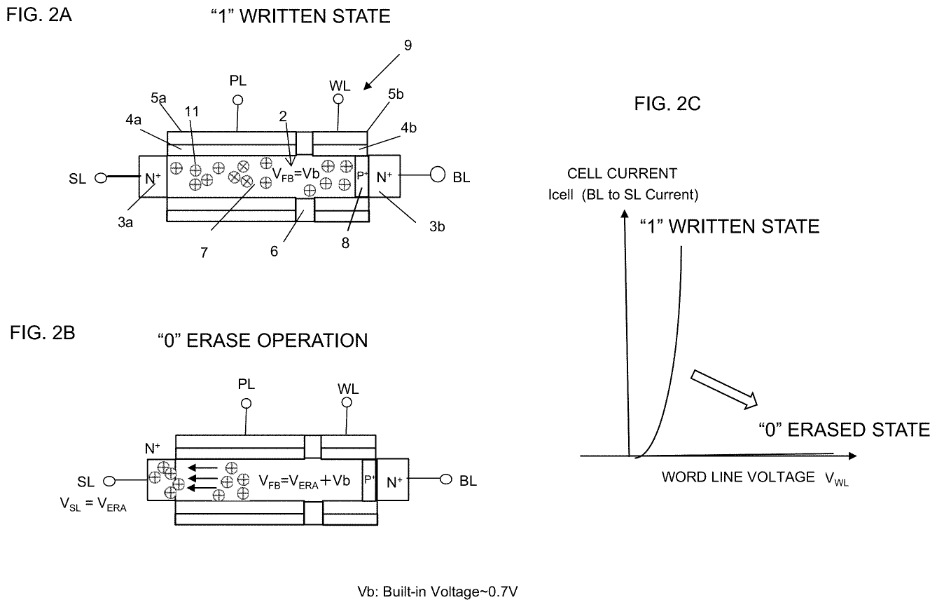

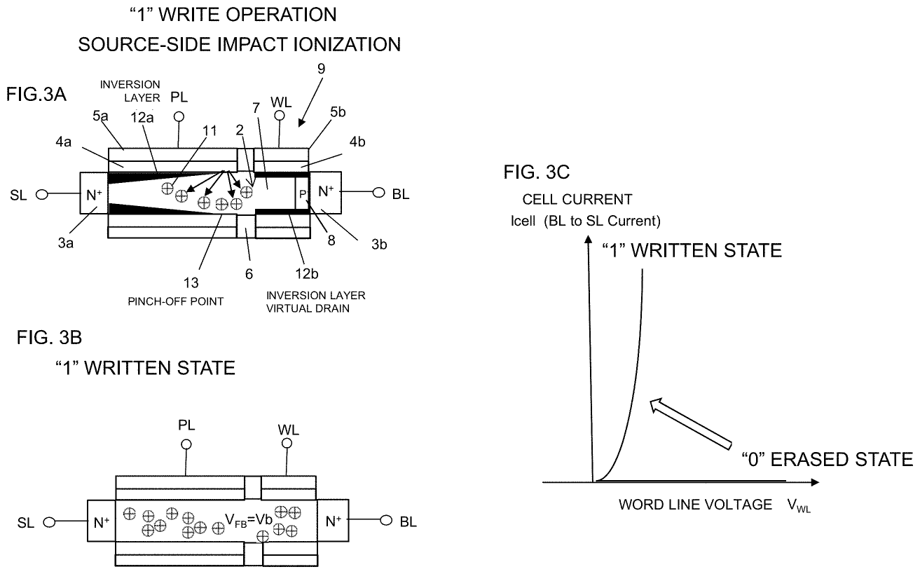

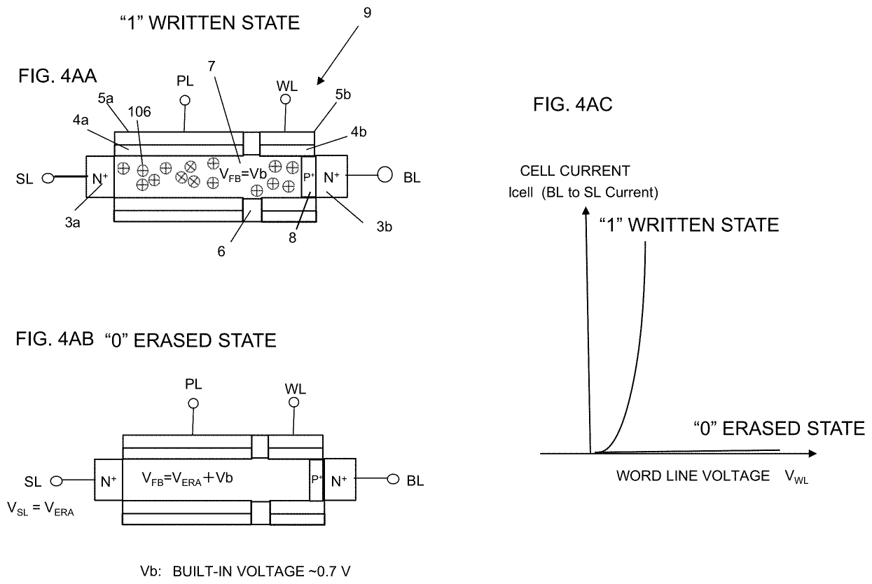

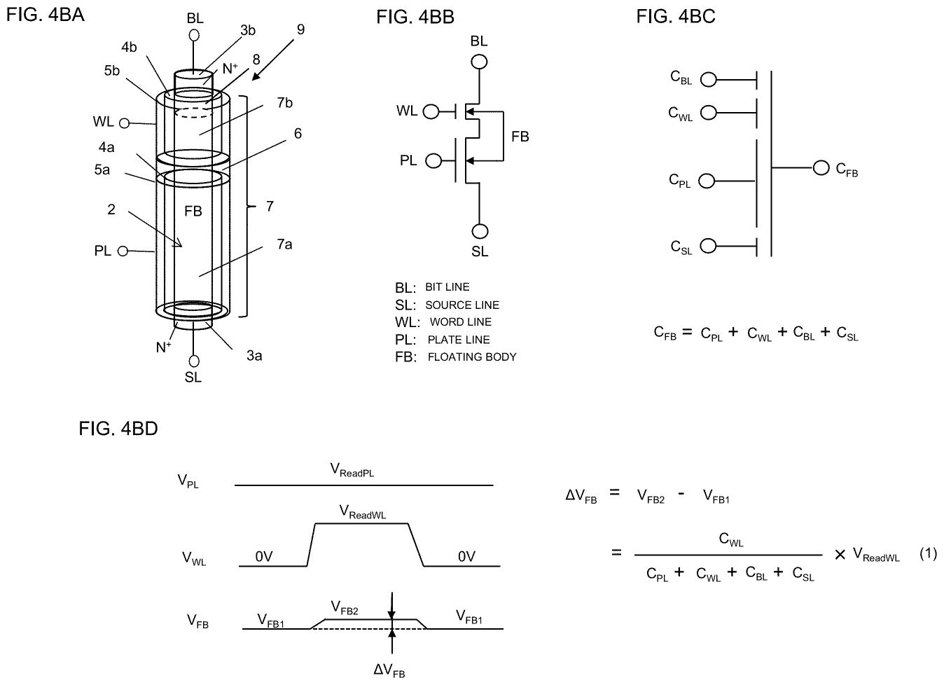

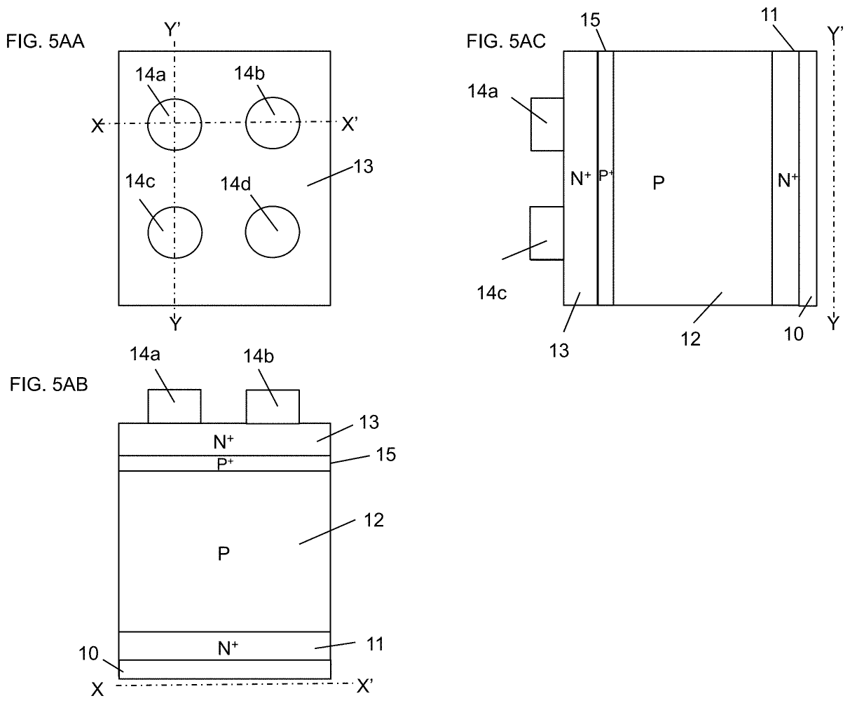

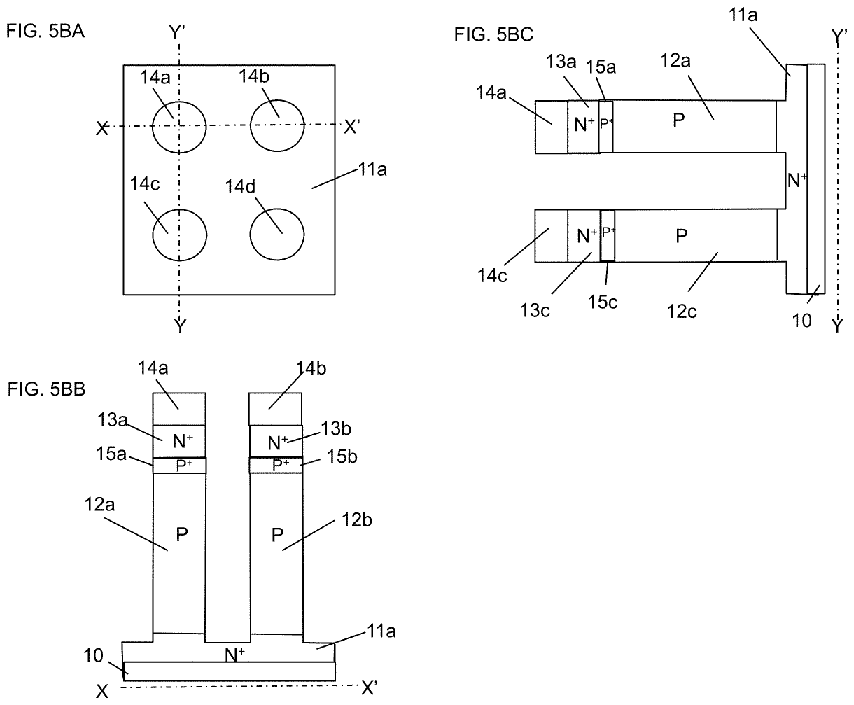

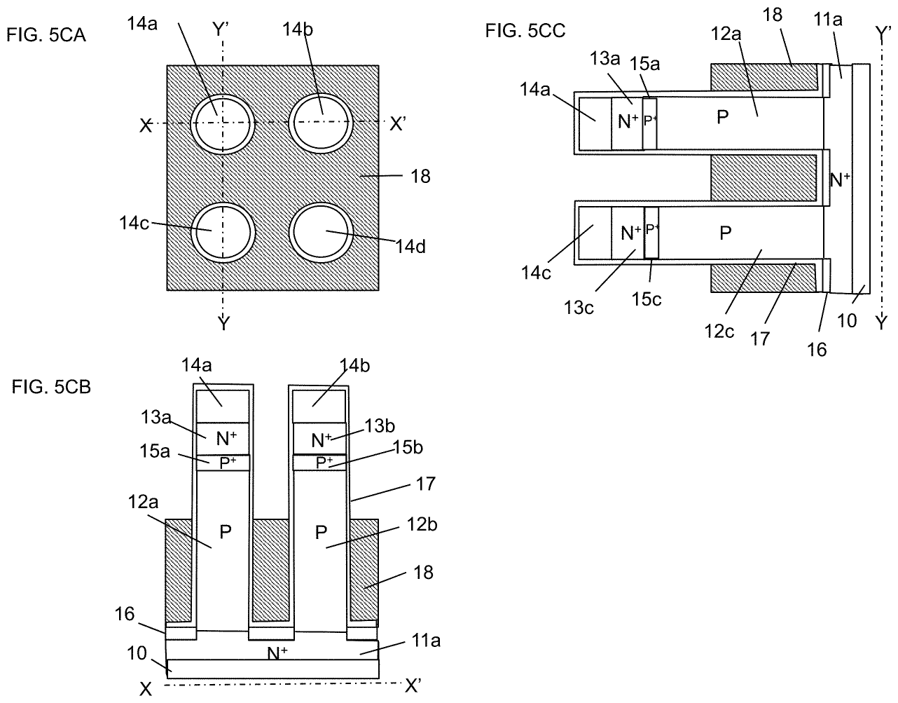

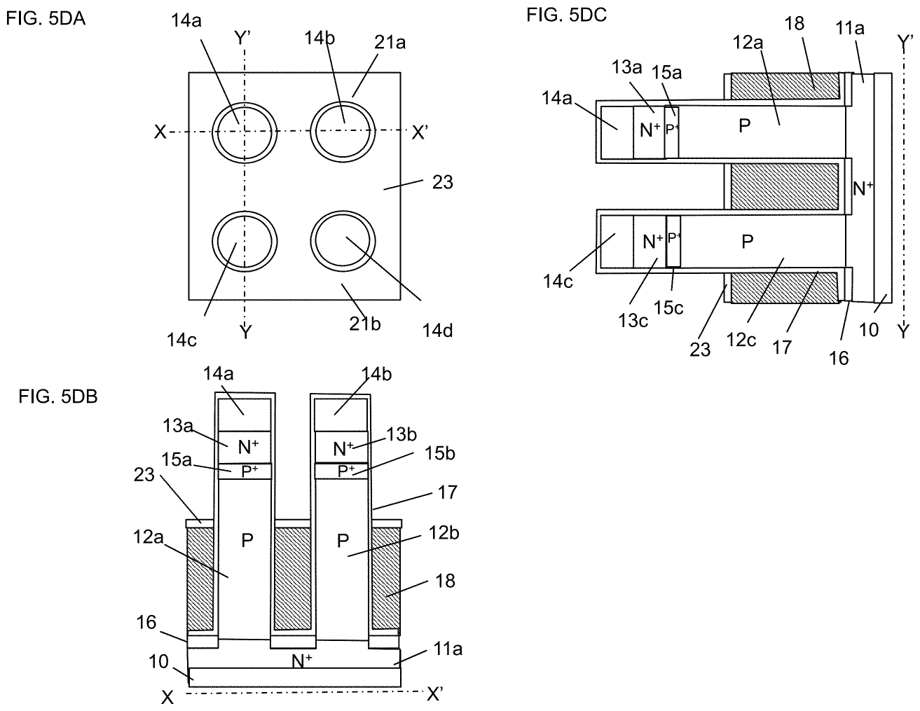

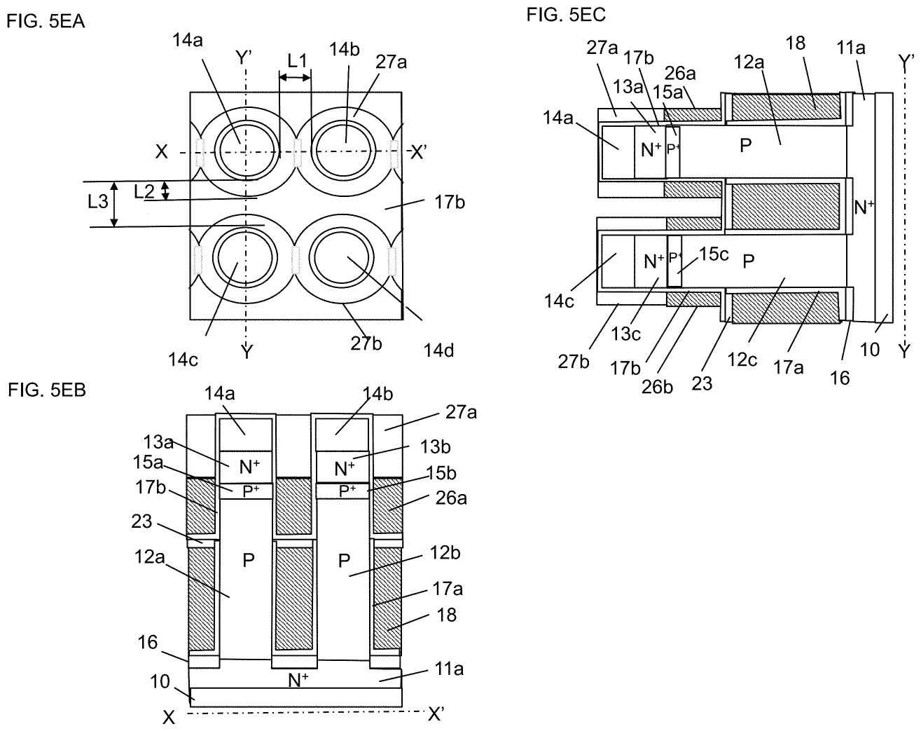

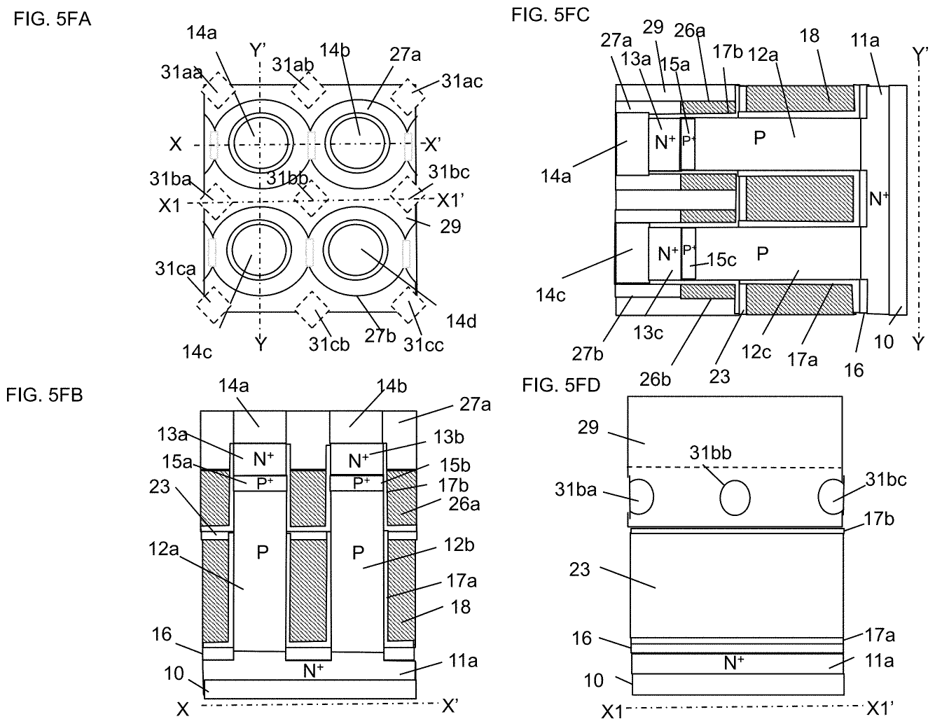

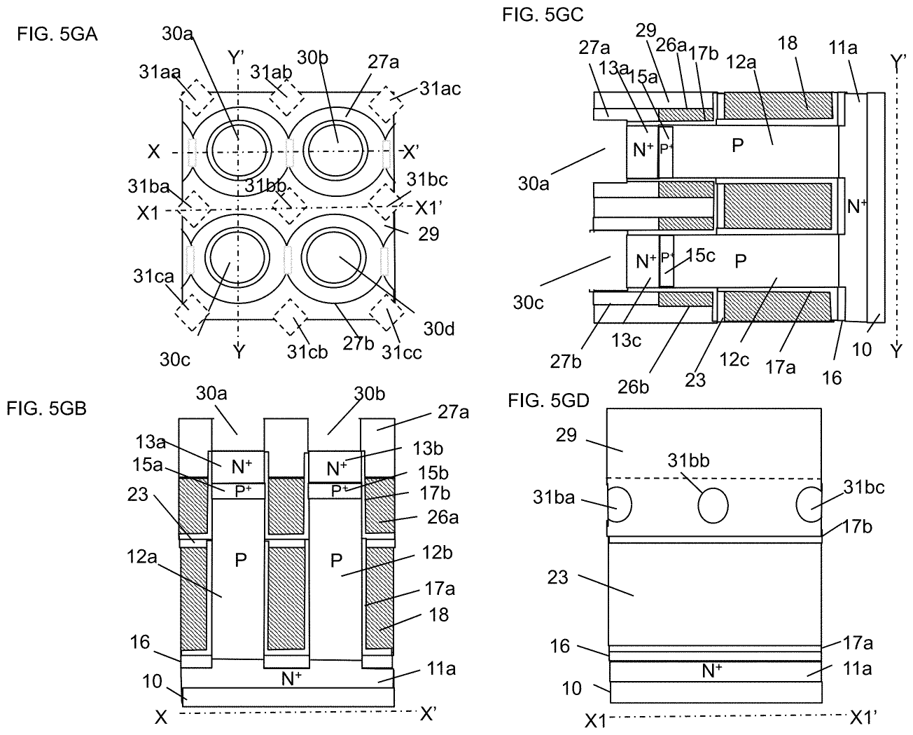

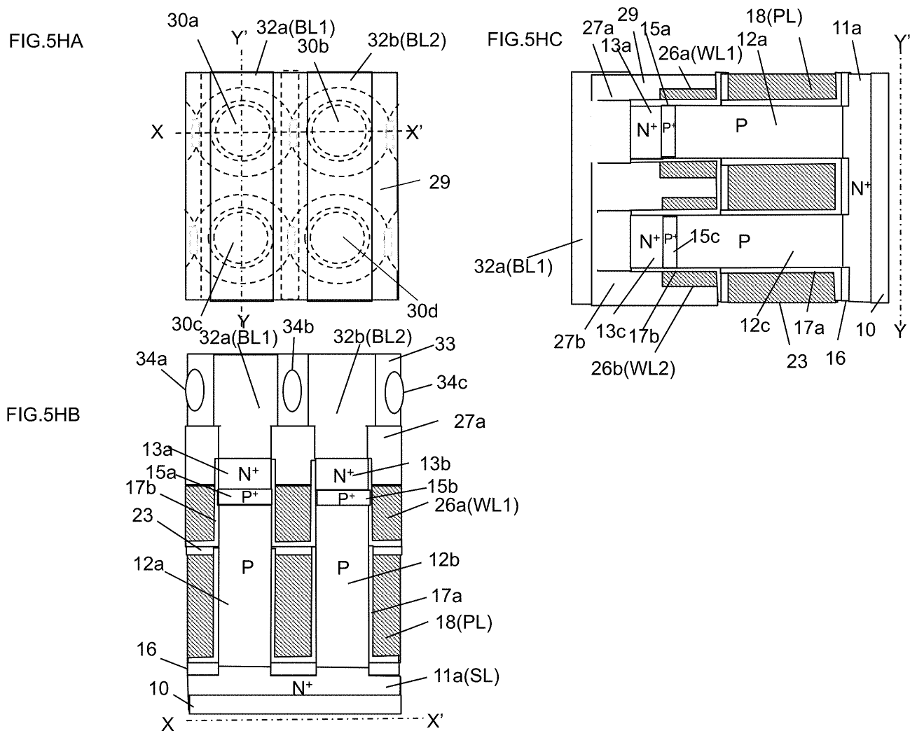

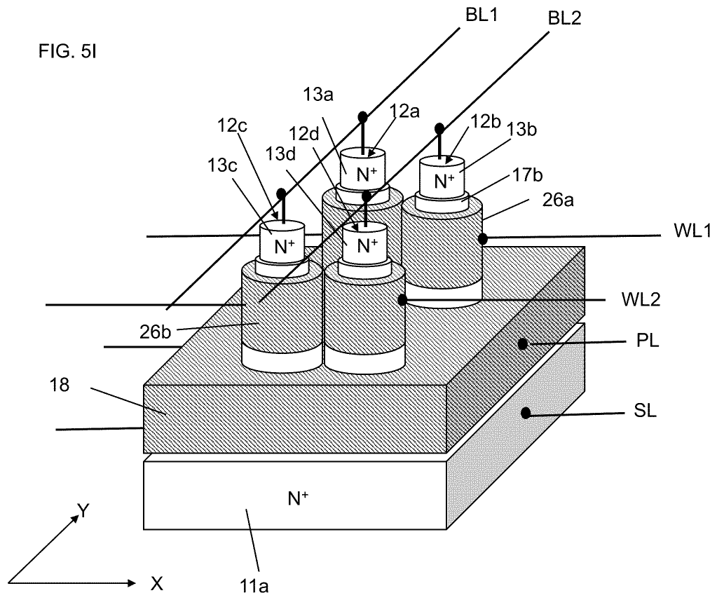

The structure, operating mechanism, and method of manufacture of a dynamic flash memory cell according to a first embodiment of the present invention will be described using FIGS. 1 to 5I. The structure of the dynamic flash memory cell will be described using FIG. 1. The data erase mechanism will be described using FIGS. 2A-2C. The data write mechanism will be described using FIGS. 3A-3C. The data read mechanism will be described using FIGS. 4A-4C. The method for manufacturing the dynamic flash memory will be described using FIGS. 5AA-5I.

FIG. 1 illustrates the structure of the dynamic flash memory cell according to the first embodiment of the present invention. An N⁺ layer 3a (an example of “first impurity layer” in the claims) and an N⁺ layer 3b (an example of “second impurity layer” in the claims), one of which serves as a source when the other serves as a drain, are formed at upper and lower positions within a silicon semiconductor pillar 2 (an example of “semiconductor base” in the claims) (a silicon semiconductor pillar is hereinafter referred to as “Si pillar”) of P-type or i-type (intrinsic type) conductivity formed on a substrate 1 (an example of “substrate” in the claims). The portion of the Si pillar 2 between the N⁺ layers 3a and 3b serving as the source and the drain serves as a channel region 7 (an example of “channel semiconductor layer” in the claims). A first gate insulating layer 4a (an example of “first gate insulating layer” in the claims) and a second gate insulating layer 4b (an example of “second gate insulating layer” in the claims) are formed so as to surround the channel region 7. The first gate insulating layer 4a and the second gate insulating layer 4b are in contact with or in proximity to the N⁺ layers 3a and 3b, respectively, serving as the source and the drain. A first gate conductor layer 5a (an example of “first gate conductor layer” in the claims) and a second gate conductor layer 5b (an example of “second gate conductor layer” in the claims) are formed so as to surround the first gate insulating layer 4a and the second gate insulating layer 4b, respectively. The first gate conductor layer 5a and the second gate conductor layer 5b are isolated by an insulating layer 6 (an example of “first insulating layer” in the claims). A P⁺ layer 8 (an example of “third impurity layer” in the claims) (a semiconductor region containing a high concentration of an acceptor impurity is hereinafter referred to as “P⁺ layer”) is in contact with the N⁺ layer 3b. The channel region 7, which is the portion of the Si pillar 2 between the N⁺ layers 3a and 3b, is composed of a first channel region 7a (an example of “first channel semiconductor layer” in the claims) surrounded by the first gate insulating layer 4a and a second channel region 7b (an example of “second channel semiconductor layer” in the claims) surrounded by the second gate insulating layer 4b. The P⁺ layer 8 is included in the second channel region 7b. Thus, a dynamic flash memory cell 9 composed of the N⁺ layers 3a and 3b serving as the source and the drain, the P⁺ layer 8, the channel region 7, the first gate insulating layer 4a, the second gate insulating layer 4b, the first gate conductor layer 5a, and the second gate conductor layer 5b is formed. The N⁺ layer 3a serving as the source is connected to a source line SL (an example of “source line” in the claims). The N⁺ layer 3b serving as the drain is connected to a bit line BL (an example of “bit line” in the claims). The first gate conductor layer 5a is connected to a plate line PL (an example of “first drive control line” in the claims). The second gate conductor layer 5b is connected to a word line WL (an example of “word line” in the claims). The P⁺ layer 8 restrains the flow of unnecessary electrons into the channel region 7 through the N⁺ layer 3b connected to the bit line BL in the dynamic flash memory due to the voltages applied to the source line SL, the plate line PL, the word line WL, and the bit line BL. It is desirable to have a structure in which the gate capacitance of the first gate conductor layer 5a having the plate line PL connected thereto is greater than the gate capacitance of the second gate conductor layer 5b having the word line WL connected thereto.

In FIG. 1, the gate length of the first gate conductor layer 5a is longer than the gate length of the second gate conductor layer 5b so that the gate capacitance of the first gate conductor layer 5a connected to the plate line PL is greater than the gate capacitance of the second gate conductor layer 5b having the word line WL connected thereto. However, alternatively, instead of setting the gate length of the first gate conductor layer 5a to longer than the gate length of the second gate conductor layer 5b, the gate insulating layers may have different thicknesses so that the thickness of the gate insulating film forming the first gate insulating layer 4a is thinner than the thickness of the gate insulating film forming the second gate insulating layer 4b. The gate insulating layers may also be formed of materials with different dielectric constants so that the dielectric constant of the gate insulating film forming the first gate insulating layer 4a is higher than the dielectric constant of the gate insulating film forming the second gate insulating layer 4b. In addition, the lengths of the gate conductor layers 5a and 5b and the thicknesses and dielectric constants of the gate insulating layers 4a and 4b may be varied in any combination so that the gate capacitance of the first gate conductor layer 5a connected to the plate line PL is greater than the gate capacitance of the second gate conductor layer 5b having the word line WL connected thereto.

The erase operation mechanism will be described using FIGS. 2A-2C. The channel region 7 between the N⁺ layers 3a and 3b is a floating body electrically isolated from the substrate. FIG. 2A illustrates a state in which a group of holes 11 generated by impact ionization in the previous cycle are accumulated in the channel region 7 before the erase operation. As illustrated in FIG. 2B, during the erase operation, the voltage of the source line SL is set to a negative voltage V_{ERA}. Here, V_{ERA} is, for example, −3 V. As a result, irrespective of the value of the initial potential of the channel region 7, the PN junction between the N⁺ layer 3a serving as the source and having the source line SL connected thereto and the channel region 7 is forward-biased. As a result, the group of holes 11 generated by impact ionization in the previous cycle and accumulated in the channel region 7 are absorbed into the N⁺ layer 3a serving as the source portion, and the potential V_{FB} of the channel region 7 is V_{FB}=V_{ERA}+Vb. Here, Vb is the built-in voltage of the PN junction and is about 0.7 V. Hence, when V_{ERA}=−3 V, the potential of the channel region 7 is −2.3 V. This value represents the potential state of the channel region 7 in the erased state. Therefore, when the potential of the channel region 7 of the floating body is a negative voltage, the threshold voltage of the N-channel MOS transistor of the dynamic flash memory cell 9 becomes higher under a substrate bias effect. Thus, as illustrated in FIG. 2C, the threshold voltage of the second gate conductor layer 5b having the word line WL connected thereto becomes higher. The erased state of the channel region 7 is logical storage data “0”. By setting the voltage applied to the first gate conductor layer 5a connected to the plate line PL to higher than the threshold voltage for logical storage data “1” and lower than the threshold voltage for logical storage data “0” during data reading, the property of not allowing a current to flow when the voltage of the word line WL is increased during reading of logical storage data “0” can be achieved, as illustrated in FIG. 2C. The above conditions for the voltages applied to the bit line BL, the source line SL, the word line WL, and the plate line PL are example conditions for performing the erase operation and may be other operational conditions where the erase operation can be performed.

FIGS. 3A-3C illustrates the write operation of the dynamic flash memory cell according to the first embodiment of the present invention. As illustrated in FIG. 3A, for example, 0 V is input to the N⁺ layer 3a having the source line SL connected thereto, 3 V is input to the N⁺ layer 3b having the bit line BL connected thereto, 2 V is input to the first gate conductor layer 5a having the plate line PL connected thereto, and 5 V is input to the second gate conductor layer 5b having the word line WL connected thereto. As a result, as illustrated in FIG. 3A, an annular inversion layer 12a is formed in the first channel region 7a inside the first gate conductor layer 5a having the plate line PL connected thereto, and a first N-channel MOS transistor region having the first gate conductor layer 5a is operated in the saturation region. As a result, a pinch-off point 13 is present in the inversion layer 12a inside the first gate conductor layer 5a having the plate line PL connected thereto. On the other hand, a second N-channel MOS transistor region having the second gate conductor layer 12b having the word line WL connected thereto is operated in the linear region. As a result, an inversion layer 12b is formed without a pinch-off point over the entire surface of the second channel region 7b inside the second gate conductor layer 5b having the word line WL connected thereto. The inversion layer 12b formed over the entire surface of the second channel region 7b inside the second gate conductor layer 5b having the word line WL connected thereto serves as a virtual drain of the second N-channel MOS transistor region having the second gate conductor layer 5b. As a result, the electric field is maximized in a first boundary region (an example of “first boundary region” in the claims) of the channel region 7 between the series-connected first N-channel MOS transistor region having the first gate conductor layer 5a and second N-channel MOS transistor region having the second gate conductor layer 5b, and an impact ionization phenomenon occurs in this region. Because this region is a region on the source side as viewed from the second N-channel MOS transistor region having the second gate conductor layer 5b having the word line WL connected thereto, this phenomenon is referred to as source-side impact ionization phenomenon. This source-side impact ionization phenomenon causes electrons to flow from the N⁺ layer 3a having the source line SL connected thereto toward the N⁺ layer 3b having the bit line connected thereto. Accelerated electrons collide with the lattice Si atoms, and the kinetic energy thereof generates electron-hole pairs. While some of the generated electrons flow into the first gate conductor layer 5a and the second gate conductor layer 5b, most of the electrons flow into the N⁺ layer 3b having the bit line BL connected thereto. In “1” writing, a gate-induced drain leakage (GIDL) current may also be used to generate electron-hole pairs and fill the floating body FB with a group of generated holes (see NPL 14). The impact ionization phenomenon may also be induced in the second channel region 7b.

As illustrated in FIG. 3B, the group of generated holes 11, which are majority carriers in the channel region 7, charge the channel region 7 to a positive bias. Because the N⁺ layer 3a having the source line SL connected thereto is at 0 V, the channel region 7 is charged to the built-in voltage Vb (about 0.7 V) of the PN junction between the N⁺ layer 3a having the source line SL connected thereto and the channel region 7. When the channel region 7 is charged to a positive bias, the threshold voltage of the first N-channel MOS transistor region and the second N-channel MOS transistor region becomes lower under a substrate bias effect. Thus, as illustrated in FIG. 3C, the threshold voltage of the N-channel MOS transistor of the second channel region 7b having the word line WL connected thereto becomes lower. This written state of the channel region 7 is assigned to logical storage data “1”.

During the write operation, electron-hole pairs may be generated using an impact ionization phenomenon or a GIDL current in a second boundary region between the first impurity layer and the first channel semiconductor layer or in a third boundary region between the second impurity layer and the second channel semiconductor layer, rather than in the first boundary region, to charge the channel region 7 with the group of generated holes 11. The above conditions for the voltages applied to the bit line BL, the source line SL, the word line WL, and the plate line PL are example conditions for performing the write operation and may be other operational conditions where the write operation can be performed.

The read operation of the dynamic flash memory cell according to the first embodiment of the present invention and the related memory cell structure will be described using FIGS. 4AA-4AC and 4BA-4BD. The read operation of the dynamic flash memory cell will be described using FIGS. 4AA to 4AC. As illustrated in FIG. 4AA, when the channel region 7 is charged to the built-in voltage Vb (about 0.7 V), the threshold voltage of the N-channel MOS transistor decreases under a substrate bias effect. This state is assigned to logical storage data “1”. As illustrated in FIG. 4AB, if the memory block selected before writing is in the erased state “0” in advance, the floating voltage V_{FB} of the channel region 7 is V_{ERA}+Vb. The written state “1” is randomly stored by the write operation. As a result, logical storage data representing logic “0” and logic “1” is created for the word line WL. As illustrated in FIG. 4AC, reading is performed by a sense amplifier using the difference between the two threshold voltages for the word line WL.

The magnitude relationship between the gate capacitances of the two gate conductor layers, i.e., the first gate conductor layer 5a and the second gate conductor layer 5b, and the related operation during the read operation of the dynamic flash memory cell according to the first embodiment of the present invention will be described using FIGS. 4BA to 4BD. It is desirable to design the first gate conductor layer 5a having the plate line PL connected thereto and the second gate conductor layer 5b having the word line WL connected thereto so that the gate capacitance of the second gate conductor layer 5b is lower than the gate capacitance of the first gate conductor layer 5a. As illustrated in FIG. 4BA, the length of the first gate conductor layer 5a having the plate line PL connected thereto in the perpendicular direction is longer than the length of the second gate conductor layer 5b having the word line WL connected thereto in the perpendicular direction so that the gate capacitance of the second gate conductor layer 5b having the word line WL connected thereto is smaller than the gate capacitance of the first gate conductor layer 5a having the plate line PL connected thereto. FIG. 4BB illustrates an equivalent circuit of one cell of the dynamic flash memory in FIG. 4BA. FIG. 4BC illustrates the coupling capacitance relationship of the dynamic flash memory. Here, C_{WL} is the capacitance of the second gate conductor layer 5b, C_{PL} is the capacitance of the first gate conductor layer 5a, C_{BL} is the capacitance of the PN junction between the N⁺ layer 3b serving as the drain and the second channel region 7b, and C_{SL} is the capacitance of the PN junction between the N⁺ layer 3a serving as the source and the first channel region 7a. As illustrated in FIG. 4BD, when the voltage of the word line WL oscillates, its operation affects the channel region 7 as noise. The potential variation ΔV_{FB} in the channel region 7 at this time is ΔV_{FB}=C_{WL}(C_{PL}+C_{WL}+C_{BL}+C_{SL})×V_{ReadWL}. Here, V_{ReadWL} is the oscillation potential of the word line WL during reading. As is obvious from equation (1), it can be understood that ΔV_{FB} becomes smaller as the contribution ratio of C_{WL} becomes smaller relative to the total capacitance of the channel region 7, C_{PL}+C_{WL}+C_{BL}+C_{SL}. To increase C_{BL}+C_{SL}, which is the capacitance of the PN junctions, for example, the diameter of the Si pillar 2 is increased. This, however, is undesirable for miniaturization of memory cells. In contrast, if the length of the first gate conductor layer 5a having the plate line PL connected thereto in the perpendicular direction is longer than the length of the first gate conductor layer 5b having the word line WL connected thereto in the perpendicular direction, ΔV_{FB} can be further reduced without decreasing the degree of integration of memory cells in plan view. The above conditions for the voltages applied to the bit line BL, the source line SL, the word line WL, and the plate line PL are example conditions for performing the read operation and may be other operational conditions where the read operation can be performed.

A method for manufacturing the dynamic flash memory according to this embodiment is illustrated using FIGS. 5AA to 5I. In these figures, each of FIGS. 5AA, 5BA, 5CA, 5DA, 5EA, 5FA, 5GA and 5HA illustrates a plan view, each of FIGS. 5AB, 5BB, 5CB, 5DB, 5EB, 5FB, 5GB and 5HB illustrates a sectional view taken along line X-X′ of a corresponding one of FIGS. 5AA, 5BA, 5CA, 5DA, 5EA, 5FA, 5GA and 5HA, and each of FIGS. 5AC, 5BC, 5CC, 5DC, 5EC, 5FC, 5GC and 5HC illustrates a sectional view taken along line Y-Y′ of a corresponding one of FIGS. 5AA, 5BA, 5CA, 5DA, 5EA, 5FA, 5GA and 5HA. Each of FIGS. 5FD and 5GD illustrates a sectional view taken along line X1-X1′. In a practical dynamic flash memory, many memory cells are formed in a two-dimensional array.

As illustrated in FIGS. 5AA-5AC, in order from bottom, an N⁺ layer 11, a P layer 12 formed of Si, a P⁺ layer 15, and an N⁺ layer 13 are formed on a substrate 10. Mask material layers 14a, 14b, 14c, and 14d that are circular in plan view are then formed. The substrate 10 may be silicon-on-insulator (SOI) or a single layer or a plurality of layers of Si or other semiconductor material. The substrate 10 may also be a single N layer or P layer or a well layer composed of a plurality of layers.

Next, as illustrated in FIGS. 5BA-5BC, the N⁺ layer 13, the P layer 12, the P⁺ layer 15, and the upper portion of the N⁺ layer 11 are etched using the mask material layers 14a to 14d as a mask to form Si pillars 12a, 12b, 12c, and 12d (not illustrated), P⁺ layers 15a, 15b, 15c, and 15d (not illustrated), and N⁺ layers 13a, 13b, 13c, and 13d (not illustrated) on an N⁺ layer 11a. It is desirable that the acceptor impurity concentration of the P⁺ layers 15a to 15d be lower than the donor impurity concentration of the N⁺ layers 13a to 13d.

Next, as illustrated in FIGS. 5CA-5CC, a gate insulating layer HfO₂ layer 17 is formed so as to cover the entire surface, for example, by atomic layer deposition (ALD). A TIN layer (not illustrated) serving as a gate conductor layer is then formed so as to cover the entire surface. The TIN layer is then polished by chemical mechanical polishing (CMP) such that the upper surface thereof is located at the upper surface of the mask material layers 14a to 14d. The TiN layer is then etched by reactive ion etching (RIE) to form a TiN layer 18 such that the upper surface thereof is located near the midpoints of the Si pillars 12a to 12d in the perpendicular direction. The HfO₂ layer 17 may be another insulating layer composed of a single layer or a plurality of layers as long as the insulating layer functions as a gate insulating layer. The TiN layer 18 may also be another conductor layer composed of a single layer or a plurality of layers as long as the conductor layer functions as a gate conductor layer. In addition, it is desirable that the TiN layer be etched such that the upper surface thereof is located above the midpoints of the Si pillars 12a to 12d in the perpendicular direction.

Next, as illustrated in FIGS. 5DA-5DC, a SiO₂ layer 23 is formed on the TiN layer 18.

Next, as illustrated in FIGS. 5EA-5EC, the portion of the HfO₂ layer 17 above the SiO₂ layer 23 is etched to form a HfO₂ layer 17a. A HfO₂ layer 17b is then formed over the entire surface. A TiN layer (not illustrated) is then formed so as to cover the entire surface by a CVD process. The TiN layer is then subjected to a CMP process and is etched by an RIE process such that the upper surface thereof is located near the lower ends of the N⁺ layers 13a to 13d. A SiN layer 27a is then formed so as to surround and extend between the side surfaces of the N⁺ layers 13a and 13b and the mask material layers 14a and 14b. Similarly, a SiN layer 27b is formed so as to surround and extend between the side surfaces of the N⁺ layers 13c and 13d and the mask material layers 14c and 14d. The TiN layer is then etched using the SiN layers 27a and 27b as a mask to form TiN layers 26a and 26b. Here, because the length L1 between the intersections of the outer periphery lines of the HfO₂ layer 17b surrounding the Si pillars 12a and 12b and line X-X′ is smaller than twice the width L2 of the SiN layers 27a and 27b on line Y-Y′, and the length L3 between the intersections of the outer periphery lines of the HfO₂ layer 17b surrounding the Si pillars 12a and 12c and line Y-Y′ is greater than twice L2, the SiN layer 27a can be formed so as to extend between the Si pillars 12a and 12b and to be separated between the Si pillars 12a and 12c. Similarly, the SiN layer 27b is formed so as to extend between the Si pillars 12c and 12d and to be separated between the Si pillars 12a and 12c.

Next, as illustrated in FIGS. 5FA-5FD, a SiO₂ layer 29 including voids 31aa, 31ab, 31ac, 31ba, 31bb, 31bc, 31ca, 31cb, and 31cc is formed between and around the side surfaces of the TiN layers 26a and 26b and the SiN layers 27a and 27b. The voids 31aa, 31ab, 31ac, 31ba, 31bb, 31bc, 31ca, 31cb, and 31cc are formed such that the upper ends thereof are located at a position lower than the upper ends of the TiN layers 26a and 26b indicated by the dotted line in FIG. 5FD.

Next, as illustrated in FIGS. 5GA-5GD, the mask material layers 14a to 14d are etched to form contact holes 30a, 30b, 30c, and 30d.

Next, as illustrated in FIGS. 5HA-5HC, a bit line BL1 conductor layer 32a connected to the N⁺ layers 13a and 13c through the contact holes 30a and 30c and a bit line BL2 conductor layer 32b connected to the N⁺ layers 13b and 13d through the contact holes 30b and 30d are formed. A SiO₂ layer 33 including voids 34a, 34b, and 34c is then formed between and on both sides of the bit line BL1 conductor layer 32a and the bit line BL2 conductor layer 32b. Thus, a dynamic flash memory is formed on the substrate 10. The TiN layers 26a and 26b serve as word line conductor layers WL1 and WL2, the TiN layer 18 serves as a plate line conductor layer PL that also functions as a gate conductor layer, and the N⁺ layer 11a serves as a source line conductor layer SL that also functions as a source impurity layer.

FIG. 5I illustrates a schematic structural view of the dynamic flash memory illustrated in FIGS. 5HA-5HC. The N⁺ layer 11a of the source line conductor layer SL is formed so as to extend over the entire surface. The plate line conductor layer PL is also formed so as to extend over the entire surface. The gate conductor TiN layer 26a connected to the word line conductor layer WL1 is formed so as to extend between the adjacent Si pillars 12a and 12b in the X direction. Similarly, the gate conductor TiN layer 26b connected to the word line conductor layer WL2 is formed so as to extend between the adjacent Si pillars 12c and 12d in the X direction. The bit line conductor layer BL1 connected to the N⁺ layers 13a and 13c and the bit line conductor layer BL2 connected to the N⁺ layers 13b and 13d are formed in the Y direction orthogonal to the X direction.

In addition, in FIG. 1, a dynamic flash memory element has been described by taking, as an example, an SGT including the first gate insulating layer 4a and the second gate insulating layer 4b surrounding the entire side surface of the Si pillar 2 standing on the substrate 1 in the perpendicular direction and the first gate conductor layer 5a and the second gate conductor layer 5b surrounding the entirety of the first gate insulating layer 4a and the second gate insulating layer 4b. As illustrated in this embodiment, it is sufficient that this dynamic flash memory element have a structure satisfying the conditions where the group of holes generated by an impact ionization phenomenon or a gate-induced drain leakage current are held in the channel region 7. Accordingly, it is sufficient that the channel region 7 have a floating body structure isolated from the substrate 1. Thus, the dynamic flash memory operation described above can be achieved even if the semiconductor base of the channel region is formed parallel to the substrate 1, for example, using gate-all-around (GAA; see, for example, NPL 11) technology and nanosheet technology (see, for example, NPL 12), which are one type of SGT. The device structure may also be one using silicon-on-insulator (SOI) (see, for example, NPLs 7 to 10). In this device structure, the bottom portion of the channel region is in contact with the insulating layer of the SOI substrate, and the remainder of the channel region is surrounded by a gate insulating layer and an element isolation insulating layer. In this structure, the channel region has a floating body structure. Thus, it is sufficient that the dynamic flash memory element provided by this embodiment satisfy the condition that the channel region has a floating body structure. This dynamic flash operation can also be achieved using a structure in which a Fin transistor (see, for example, NPL 13) is formed on an SOI substrate as long as the channel region has a floating body structure.

In FIG. 1, the length of the first gate conductor layer 5a having the plate line PL connected thereto in the perpendicular direction is longer than the length of the second gate conductor layer 5b having the word line WL connected thereto in the perpendicular direction, i.e., C_{PL}>C_{WL}. However, the capacitive coupling ratio (C_{WL}/(C_{PL}+C_{WL}+C_{BL}+C_{SL})) of the word line WL with the channel region 7 is reduced simply by adding the plate line PL. As a result, the potential variation ΔV_{FB} in the channel region 7 of the floating body is reduced.

In addition, for example, a fixed voltage of 2 V may be applied as the voltage V_{ErasePL} of the plate line PL irrespective of the mode of operation. In addition, for example, a voltage of 0 V may be applied as the voltage V_{ErasePL} of the plate line PL only during erase. In addition, a fixed voltage or a time-varying voltage may be applied as the voltage V_{ErasePL} of the plate line PL as long as the voltage satisfies the conditions where the dynamic flash memory operation can be achieved.

In addition, in FIG. 1, the dynamic flash memory operation described in this embodiment can also be achieved when the transverse sectional shape of the Si pillar 2 is circular, oval, or rectangular. In addition, circular, oval, and rectangular dynamic flash memory cells may coexist on the same chip.

In addition, in FIG. 1, the potential distributions of the first channel region 7a and the second channel region 7b are formed so as to be connected together in the perpendicular direction in the portion of the channel region 7 surrounded by the insulating layer 6. Thus, the first channel region 7a and the second channel region 7b of the channel region 7 are connected together in the perpendicular direction in the region surrounded by the insulating layer 6.

As illustrated in FIGS. 5HA-5HC, the N⁺ layer 11a also functions as a wiring conductor layer for the source line SL. For example, a conductor layer such as a W layer formed between portions of the N⁺ layer 11a at the bottom portions of the Si pillars 12a to 12d may also be used as the source line SL. In addition, for example, a conductor layer such as a W layer may be formed on the N⁺ layer 11a outside a region in which many Si pillars 12a to 12d are formed in a two-dimensional array.

In addition, as illustrated in FIGS. 5AA-5AC, the P⁺ layers 15a to 15d are formed from the P⁺ layer 15, which is formed by an epitaxial growth process. Alternatively, the P⁺ layers 15a to 15d may be formed by an ion implantation process. In addition, the P⁺ layers 15a to 15d may be formed by incorporating an acceptor impurity into the N⁺ layer 13 at a concentration lower than the donor impurity concentration and thermally diffusing the acceptor impurity from the N⁺ layer 13 to the P layer 12 side in the subsequent thermal process. The acceptor impurity selected in this case is an impurity having a higher thermal diffusion coefficient than the donor impurity. In addition, the P⁺ layers 15a to 15b may be formed before or after the formation of the TiN layer 26a.

In addition, one or all of the first gate conductor layer 5a and the second gate conductor layer 5b may be split into two or more sections in plan view, and each section may be operated synchronously or asynchronously as a conductor electrode for the plate line or the word line. A dynamic flash memory operation can also be achieved in this way.

In addition, one or both of the first gate conductor layer 5a and the second gate conductor layer 5b may be split in the perpendicular direction. Each section may be operated synchronously or asynchronously. A dynamic flash memory operation can also be achieved in this way.

In addition, in FIGS. 5AA-5I, the Si pillars 12a to 12d are arranged in a square grid pattern in plan view. Alternatively, the Si pillars 12a to 12d may be arranged in an oblique grid pattern. In addition, the Si pillars 12a to 12d may be arranged in a zigzag or serrated pattern such that each side is formed by two or more Si pillars connected to one word line.

This embodiment provides the following features.

### Feature 1

The plate line PL of the dynamic flash memory cell according to the first embodiment of the present invention functions to reduce the capacitive coupling ratio between the word line WL and the channel region 7 when the voltage of the word line WL oscillates up and down during the write or read operation of the dynamic flash memory cell. As a result, the effect of variations in the voltage of the channel region 7 can be considerably reduced when the voltage of the word line WL oscillates up and down. Thus, the difference between the SGT transistor threshold voltages of the word line WL that represent logic “0” and logic “1” can be increased. This leads to a broader margin of operation of the dynamic flash memory cell. By setting the voltage applied to the first gate conductor layer 5a connected to the plate line PL to higher than the threshold voltage for logical storage data “1” and lower than the threshold voltage for logical storage data “0” during data reading, the property of not allowing a current to flow when the voltage of the word line WL is increased during reading of logical storage data “0” can be achieved. This leads to an even broader margin of operation of the dynamic flash memory cell.

### Feature 2

The P⁺ layer 8 in FIG. 1 restrains the flow of unnecessary electrons into the channel region 7 through the N⁺ layer 3b connected to the bit line BL in the dynamic flash memory due to the voltages applied to the source line SL, the plate line PL, the word line WL, and the bit line BL or the effect of capacitive coupling noise from the surrounding memory cells. This allows the dynamic flash memory to operate stably and thus leads to a higher performance.

### Second Embodiment

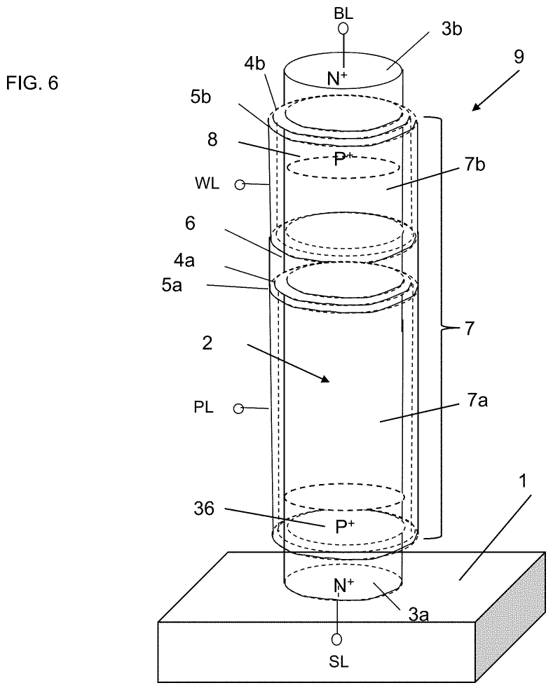

A dynamic flash memory of a second embodiment will be described using FIG. 6.

As illustrated in FIG. 6, a P⁺ layer 36 is formed in contact with the N⁺ layer 3a in the bottom portion of the Si pillar 2 in FIG. 1. The rest is the same as in FIG. 1.

It is desirable that the acceptor impurity concentration of the P⁺ layer 36 be lower than or equal to the acceptor impurity concentration of the P⁺ layer 8.

This embodiment provides the following features.

### Feature 1

As with the P⁺ layer 8, the P⁺ layer 36 restrains the flow of unnecessary electrons into the channel region 7 through the N⁺ layer 3a connected to the source line SL in the dynamic flash memory due to the voltages applied to the source line SL, the plate line PL, the word line WL, and the bit line BL or the effect of capacitive coupling noise from the surrounding memory cells. This allows the dynamic flash memory to operate stably and thus leads to a higher performance.

### Feature 2

As illustrated in FIGS. 4AA-4BC, the junction capacitance C_{SL} between the N⁺ layer 3a and the P⁺ layer 36 contributes to a potential variation in the channel region 7. From this viewpoint, it is desirable that the junction capacitance C_{SL} between the N⁺ layer 3a and the P⁺ layer 36 be smaller. In the dynamic flash memory, the memory cells are arranged in a two-dimensional array, and the N⁺ layer 3a connected to the source line SL is formed so as to extend between the cells within the blocks. Thus, the potential variation due to capacitive coupling from the adjacent memory cells is smaller than that in the N⁺ layer 3b connected to the bit line BL. Thus, if the P⁺ layer 36 has a lower acceptor impurity concentration than the P⁺ layer 8, it is possible to restrain the flow of unnecessary electrons into the channel region 7 through the N⁺ layer 3a connected to the source line SL in the dynamic flash memory due to the voltages applied to the source line SL, the plate line PL, the word line WL, and the bit line BL or the effect of capacitive coupling noise from the surrounding memory cells, while reducing the potential variation in the channel region 7. This allows the dynamic flash memory to operate stably and thus leads to a higher performance.

### Third Embodiment

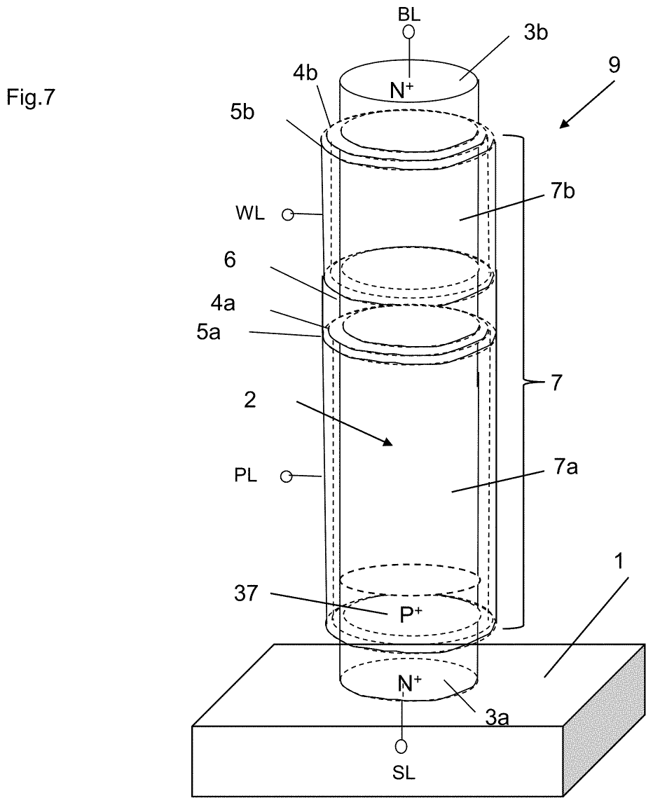

A dynamic flash memory of a third embodiment will be described using FIG. 7.

As illustrated in FIG. 7, a P⁺ layer 37 is formed in contact with the N⁺ layer 3a in the bottom portion of the Si pillar 2 in FIG. 1. The P⁺ layer 8 in contact with the N⁺ layer 3b in the top portion of the Si pillar 2 in FIG. 1 is not formed. The rest is the same as in FIG. 1.

This embodiment provides the following feature.

The P⁺ layer 37 restrains the flow of unnecessary electrons into the channel region 7 through the N⁺ layer 3a connected to the source line SL in the dynamic flash memory due to the voltages applied to the source line SL, the plate line PL, the word line WL, and the bit line BL or the effect of capacitive coupling noise from the surrounding memory cells. This allows the dynamic flash memory to operate stably and thus leads to a higher performance.

### Other Embodiments

Although the Si pillars 2 and 12a to 12d are formed in the above embodiments, they may be replaced by semiconductor pillars formed of semiconductor materials other than Si. This also applies to other embodiments according to the present invention.

In addition, the N⁺ layers 3a, 3b, 11, and 13 in the first embodiment may be formed of Si containing a donor impurity or another semiconductor material layer. In addition, the N⁺ layers 3a, 3b, 11, and 13 may be formed of different semiconductor material layers. In addition, these N⁺ layers may be formed by an epitaxial crystal growth process or another process. In addition, the P⁺ layers 15a to 15b may also be formed of Si containing an acceptor impurity or another semiconductor material layer. In addition, these P⁺ layers may be formed by an epitaxial crystal growth process or another process. This also applies to other embodiments according to the present invention.

In addition, the TiN layer 18 is used as the plate line PL and the gate conductor layer 5a connected to the plate line PL in the first embodiment. Alternatively, a single conductive material layer or a combination of a plurality of conductive material layers may be used instead of the TiN layer 18. Similarly, the TiN layers 26a and 26b are used as the word line WL and the gate conductor layer 5b connected to the word line WL. Alternatively, a single conductive material layer or a combination of a plurality of conductive material layers may be used instead of the TiN layers 26a and 26b. In addition, the gate TiN layer may be connected on its outside to a wiring metal layer such as a W layer. This also applies to other embodiments according to the present invention.

In addition, the shape of the Si pillars 12a to 12d in plan view is circular in the first embodiment. The shape of the Si pillars 12a to 12d in plan view may be, for example, circular, oval, or elongated in one direction. Si pillars having different shapes in plan view can also be formed in a logic circuit region formed away from the dynamic flash memory cell region depending on the logic circuit design. These also apply to other embodiments according to the present invention.

In addition, although the source line SL is set to a negative bias to withdraw a group of holes from the channel region 7 serving as the floating body FB during the erase operation in the first embodiment, the erase operation may also be performed by setting the bit line BL to a negative bias instead of the source line SL or setting the source line SL and the bit line BL to a negative bias. Alternatively, the erase operation may be performed under other voltage conditions. This also applies to other embodiments according to the present invention.

In addition, in the present invention, various embodiments and modifications can be made without departing from the broad spirit and scope of the present invention. In addition, the foregoing embodiments are intended to illustrate an example of the present invention and not to limit the scope of the present invention. The foregoing embodiments and modifications can be used in any combination. Furthermore, embodiments obtained by excluding some requirements from the foregoing embodiments as needed are also included within the scope of the technical idea of the present invention.

### INDUSTRIAL APPLICATION

A memory device using a semiconductor element and a method for manufacturing the memory device according to the present invention provide a high-density, high-performance dynamic flash memory.

What is claimed is:

1. A memory device using a semiconductor element, comprising:
a semiconductor base standing on a substrate in a direction perpendicular to the substrate or extending on the substrate in a direction parallel to the substrate;
a first impurity layer and a second impurity layer at both ends of the semiconductor base;
a third impurity layer formed in the semiconductor base at one or both of a position adjoining the first impurity layer and a position adjoining the second impurity layer, the third impurity layer having an opposite conductivity to the first impurity layer and the second impurity layer;
a first gate insulating layer surrounding a portion or entirety of a side surface of the semiconductor base between the first impurity layer and the second impurity layer, the first gate insulating layer being in contact with or in proximity to the first impurity layer;
a second gate insulating layer surrounding a portion or entirety of the side surface of the semiconductor base, the second gate insulating layer being connected to the first gate insulating layer and being in contact with or in proximity to the second impurity layer;
a first gate conductor layer covering the first gate insulating layer;
a second gate conductor layer covering the second gate insulating layer;
a first insulating layer between the first gate conductor layer and the second gate conductor layer;
a first wiring conductor layer connected to the first impurity layer;
a second wiring conductor layer connected to the second impurity layer;
a third wiring conductor layer connected to the first gate conductor layer;
a fourth wiring conductor layer connected to the second gate conductor layer; and
a channel semiconductor layer comprising a first channel semiconductor layer of the semiconductor base that is covered by the first gate insulating layer and a second channel semiconductor layer of the semiconductor base that is covered by the second gate insulating layer and that is directly connected to the first channel semiconductor layer,
wherein a memory write operation is performed by controlling voltages applied to the first wiring conductor layer, the second wiring conductor layer, the third wiring conductor layer, and the fourth wiring conductor layer to perform an operation of causing an impact ionization phenomenon or a gate-induced drain leakage current with a current flowing between the first impurity layer and the second impurity layer in a first boundary region between the first channel semiconductor layer and the second channel semiconductor layer, a second boundary region between the first impurity layer and the first channel semiconductor layer, or a third boundary region between the second impurity layer and the second channel semiconductor layer, an operation of removing, of a group of generated electrons and a group of generated holes, the group of electrons from the first impurity layer or the second impurity layer, and an operation of allowing some or all of the group of holes to remain in one or both of the first channel semiconductor layer and the second channel semiconductor layer, and
a memory erase operation is performed by controlling the voltages applied to the first wiring conductor layer, the second wiring conductor layer, the third wiring conductor layer, and the fourth wiring conductor layer to extract a remainder of the group of holes from one or both of the first impurity layer and the second impurity layer.

2. The memory device using a semiconductor element according to claim 1,
wherein a wiring line connected to the first impurity layer is a source line, a wiring line connected to the second impurity layer is a bit line, one of a wiring line connected to the first gate conductor layer and a wiring line connected to the second gate conductor layer is connected to a first drive control line, and the other wiring line is connected to a word line, and
the memory erase operation and the memory write operation are performed using voltages applied to the source line, the bit line, the first drive control line, and the word line.

3. The memory device using a semiconductor element according to claim 2,
wherein a fourth impurity layer that is the third impurity layer is formed at a position adjoining the second impurity layer.

4. The memory device using a semiconductor element according to claim 2,
wherein a fifth impurity layer that is the third impurity layer is formed at a position adjoining the first impurity layer.

5. The memory device using a semiconductor element according to claim 2,
wherein a sixth impurity layer that is the third impurity layer is formed at a position adjoining the first impurity layer, and a seventh impurity layer that is the third impurity layer is formed at a position adjoining the second impurity layer connected to the bit line.

6. The memory device using a semiconductor element according to claim 1,
wherein a first gate capacitance between the first gate conductor layer and the first channel semiconductor layer is greater than a second gate capacitance between the second gate conductor layer and the second channel semiconductor layer.

7. A method for manufacturing a memory device using a semiconductor element, the memory device including:
a first semiconductor pillar standing on a substrate;
a first impurity layer and a second impurity layer at both ends of the first semiconductor pillar;
a first gate insulating layer surrounding the first semiconductor pillar between the first impurity layer and the second impurity layer, the first gate insulating layer being in contact with or in proximity to the first impurity layer;
a second gate insulating layer surrounding the first semiconductor pillar, the second gate insulating layer being connected to the first gate insulating layer and being in contact with or in proximity to the second impurity layer;
a first gate conductor layer surrounding the first gate insulating layer;
a second gate conductor layer surrounding the second gate insulating layer; and
a first channel semiconductor layer of the first semiconductor pillar that is surrounded by the first gate insulating layer and a second channel semiconductor layer of the first semiconductor pillar that is surrounded by the second gate insulating layer and that is directly connected to the first channel semiconductor layer,
wherein voltages applied to the first impurity layer, the second impurity layer, the first gate conductor layer, and the second gate conductor layer are controlled to perform an operation of causing an impact ionization phenomenon or a gate-induced drain leakage current with a current flowing between the first impurity layer and the second impurity layer, an operation of removing, of a group of generated electrons and a group of generated holes, the group of electrons from the first impurity layer or the second impurity layer, an operation of allowing some or all of the group of holes to remain in the first semiconductor pillar, and a memory erase operation by extracting a remainder of the group of holes from one or both of the first impurity layer and the second impurity layer,
the method comprising the steps of:
forming the first semiconductor pillar standing perpendicular to the substrate;
forming the first impurity layer in a bottom portion of the first semiconductor pillar;
forming the first gate insulating layer surrounding a lower portion of the first semiconductor pillar;
forming the first gate conductor layer surrounding the first gate insulating layer;
forming the second gate insulating layer connected to the first gate insulating layer on the first semiconductor pillar and surrounding an upper portion of the first semiconductor pillar;
forming the second gate conductor layer surrounding the second gate insulating layer;
forming the second impurity layer in a top portion of the first semiconductor pillar; and
forming a third impurity layer in the first semiconductor pillar at one or both of a position adjoining the first impurity layer and a position adjoining the second impurity layer, the third impurity layer having an opposite conductivity to the first impurity layer and the second impurity layer.

8. The method for manufacturing the memory device using a semiconductor element according to claim 7,
wherein a source line wiring layer is formed so as to be connected to the first impurity layer,
a bit line wiring layer is formed so as to be connected to the second impurity layer,
a first drive control line wiring layer connected to one of the first gate conductor layer and the second gate conductor layer is formed, and a word line wiring layer connected to the other gate conductor layer is formed, and
the memory erase operation and the memory write operation are performed using the voltages applied to the source line wiring layer, the bit line wiring layer, the first drive control line wiring layer, and the word line wiring layer.

9. The method for manufacturing the memory device using a semiconductor element according to claim 8, further comprising the step of:
forming a fourth impurity layer that is the third impurity layer at a position adjoining the second impurity layer.

10. The method for manufacturing the memory device using a semiconductor element according to claim 8, further comprising the step of:
forming a fifth impurity layer that is the third impurity layer at a position adjoining the first impurity layer.

11. The method for manufacturing the memory device using a semiconductor element according to claim 8, further comprising the steps of:
forming a sixth impurity layer that is the third impurity layer at a position adjoining the first impurity layer and forming a seventh impurity layer that is the third impurity layer at a position adjoining the second impurity layer connected to the bit line wiring layer.

12. The method for manufacturing the memory device using a semiconductor element according to claim 7, further comprising the steps of:
incorporating a donor impurity and an acceptor impurity having a greater thermal diffusion coefficient than the donor impurity into one or both of the first impurity layer and the second impurity layer such that a concentration of the acceptor impurity is lower than a concentration of the donor impurity; and then
forming the third impurity layer in the first semiconductor pillar by heat treatment.

13. The method for manufacturing the memory device using a semiconductor element according to claim 7,
wherein the memory device is formed such that a first gate capacitance between the first gate conductor layer and the first semiconductor pillar is greater than a second gate capacitance between the second gate conductor layer and the first semiconductor pillar.
